(19) United States
(12) Patent Application Publication
(10) Pub. No.: US 2025/0098507 A1
(43) Pub. Date: Mar. 20, 2025

(54) Display Panel and Display Device

(71) Applicants: Beijing BOE Optoelectronics Technology Co., Ltd., Beijing (CN); BOE Technology Group Co., Ltd., Beijing (CN)

(72) Inventors: Xiaotian PANG, Beijing (CN); Jiaqiang WANG, Beijing (CN); Xiantao LIU, Beijing (CN); Yunshan WANG, Beijing (CN); Chen MENG, Beijing (CN); Yonghui WANG, Beijing (CN); Wei SUN, Beijing (CN); Siheng XU, Beijing (CN); Dahai HU, Beijing (CN); Ziyan LI, Beijing (CN); Zhong HU, Beijing (CN)

(21) Appl. No.: 18/292,939

(22) PCT Filed: Feb. 20, 2023
(86) PCT No.: PCT/CN2023/077110

§ 371 Date: Jan. 29, 2024

(30) Foreign Application Priority Data
Mar. 14, 2022 (CN) 202210248760.9

(51) Int. Cl. H10K 59/80; H10K 59/131

(52) U.S. Cl. CPC H10K 59/8794; H10K 59/131

(57) ABSTRACT

The present disclosure provides a display panel and a display device, pertains to the field of display technologies. The present disclosure provides a display panel at least including a display region. The display panel includes a base substrate and a plurality of sub-pixels disposed on the base substrate, a sub-pixel at least includes a light emitting device, and the light emitting device is located in the display region. The light emitting device includes a first electrode, a light emitting layer, and a second electrode provided in sequence in a direction facing away from a base substrate. The display panel further includes a heat conduction structure disposed on a side of the first electrode facing away from the light emitting layer, and orthographic projections of the heat conduction structure and the first electrode on the base substrate are at least partially overlapped with each other.

### CROSS-REFERENCE TO RELATED APPLICATIONS

The present application is a U.S. National Phase Entry of International Application PCT/CN2023/077110 having an international filing date of Feb. 20, 2023 claims priority of Chinese patent application No. 202210248760.9, filed to the CNIPA on Mar. 14, 2022, and entitled “Display Panel and Display Device”, the contents of which should be interpreted as being incorporated herein by reference.

### TECHNICAL FIELD

The present disclosure pertains to the field of display technologies, and particularly to a display panel and a display device.

### BACKGROUND

Organic Light Emitting Diodes (OLED's) are new current control semiconductor light emitting devices, which are excited by controlling carrier injection and compound excitation of organic materials, pertaining to a self-luminescence technology. Compared with passive luminous Liquid Crystal Display (LCD for short), self-luminescent OLED displays have advantages of fast response speed, high contrast, wide viewing angle, etc., and are easy to achieve flexible display, which is generally favored by the industry. The industry agrees that OLED display is likely to become a major product of the next generation display technology.

When an electrode material of the Organic light emitting Diode (OLED) is made of a high light-transmittance material, a transparent display panel can be manufactured. The transparent display panel can not only transmit light like a glass, but also display images like a screen, which has a large market space in applications such as architectural glasses, car glasses and exhibition.

An OLED transparent display panel applied to a vehicle glass has disadvantages of a high temperature of the OLED display panel and deterioration of the OLED display panel in a high temperature environment.

### SUMMARY

The present disclosure aims at solving at least one of technical problems existing in the prior art, and provides a display panel and a display device.

In a first aspect, the present disclosure provides a display panel including, at least, a display region that includes a base substrate and a plurality of sub-pixels disposed on the base substrate, wherein each of the sub-pixels at least includes a light emitting device that is located in the display region; the light emitting device includes a first electrode, a light emitting layer and a second electrode disposed in sequence in a direction facing away from the base substrate; the display panel further includes a heat conduction structure disposed on a side of each first electrode facing away from the light emitting layer, and an orthographic projection of the heat conduction structure on the base substrate at least partially overlaps with an orthographic projection of the first electrode on the base substrate.

The heat conduction structures and the light emitting devices are disposed in one-to-one correspondence.

The display panel further includes a heat dissipation structure that is disposed on the side of the heat conduction structure facing away from the first electrode.

The heat conduction structure includes a first heat conduction sheet, a semiconductor layer, and a second heat conduction sheet arranged in sequence in the direction facing away from the light emitting layer; wherein the first heat conduction sheet is connected to the first electrode of the light emitting device, and the second heat conduction sheet is connected to the heat dissipation structure.

The heat conduction structure includes a first heat conduction sheet, a semiconductor layer, and a second heat conduction sheet arranged in sequence in the direction facing away from the light emitting layer; wherein an insulating heat conduction layer is provided between the first heat conduction sheet and the first electrode of the light emitting device, and the second heat conduction sheet is connected to the heat dissipation structure.

The display panel is divided into a plurality of pixel units, each of the pixel units includes a plurality of sub-pixels, and at least part of heat conduction structures corresponding to each pixel unit has an integral structure.

The heat conduction structure and the heat dissipation structure are disposed on a side of the base substrate close to the first electrode.

The heat conduction structure is disposed on a side of the base substrate close to the first electrode; and the heat dissipation structure is disposed on a side of the base substrate facing away from the first electrode.

A material of the heat dissipation structure includes a copper alloy.

The heat conduction structure is disposed on a side of the base substrate facing away from the light emitting device.

The display panel further includes a plurality of first control signal lines and a plurality of second control signal lines; wherein one of the heat conduction structures is electrically connected to one of the first control signal lines and one of the second control signal lines.

The display panel further includes a plurality of first display signal lines, wherein orthographic projections of the first control signal lines and the second control signal lines on the base substrate overlap with an orthographic projection of the first display signal lines on the base substrate respectively, and the orthographic projections of the first control signal lines and the second control signal lines on the base substrate are not overlapped with each other.

The heat conduction structure includes a first heat conduction sheet, a semiconductor layer, and a second heat conduction sheet disposed in sequence in a direction facing away from the light emitting layer, and the first control signal lines and the second control signal lines are electrically connected with the semiconductor layer respectively and are disposed in a same layer as the semiconductor layer.

The heat conduction structures are arranged in an array on a side of the base substrate close to the first electrode, and a first control signal line and a second control signal line connected to a same heat conduction structure are located on two opposite sides of the heat conduction structure.

The display panel includes a plurality of heat conduction structures arranged sequentially in a column direction; heat conduction structures located in a same column are connected with a same first control signal line and a same second control signal line; heat conduction structures in columns are divided into a plurality of heat conduction structure groups, and heat conduction structures in different groups are different; and a first control signal line to which heat conduction structures in a heat conduction structure group are connected is shorted, and a second control signal line to which the heat conduction structures in the heat conduction structure group are connected is shorted.

Each column of heat conduction structures is divided into three groups of heat conduction structures, the three groups of heat conduction structures are different from each other, and every three columns of heat conduction structures are located in the three different heat conduction structure groups in sequence.

The heat conduction structures are divided into a plurality of heat conduction structure groups arranged in an array; a first control signal line to which heat conduction structures in a heat conduction structure group are connected is shorted, and a second control signal line to which the heat conduction structures in the heat conduction structure group are connected is shorted.

The display panel further includes a first drive circuit that is electrically connected to the heat conduction structure; the first drive circuit is configured to provide a first control signal to the heat conduction structure according to a temperature of the display panel; and the heat conduction structure is configured to transfer heat emitted by the light emitting device under a control of the first control signal.

The display panel further includes a temperature sensing component and a first controller; wherein the temperature sensing component is disposed on a side of the first electrode facing away from the light emitting layer, and an orthographic projection of the temperature sensing component on the base substrate at least partially overlaps with the orthographic projection of the first electrode on the base substrate; the temperature sensing component is configured to generate a first sensing signal according to the temperature of the display panel, and the first controller is configured to control operation of the heat conduction structure according to the first sensing signal.

The display panel further includes at least one first sensing signal line and at least one second sensing signal line; wherein the at least one first sensing signal line and the at least one second sensing signal line are connected to the temperature sensing component respectively.

The display panel further includes a plurality of second display signal lines; wherein orthographic projections of the first sensing signal lines and the second sensing signal lines on the base substrate are respectively overlapped with an orthographic projection of the second display signal lines on the base substrate, and the orthographic projections of the first sensing signal lines and the second sensing signal lines on the base substrate are not overlapped with each other.

The display panel further includes a temperature conversion circuit; wherein the temperature conversion circuit is configured to convert the first sensing signal into an electrical signal and transmit it to the first controller.

The temperature sensing component includes at least one of a thermistor or thermocouple.

The display panel is a transparent display panel, the display panel further includes a transparent region, and the orthographic projection of the heat conduction structure on the base substrate is not overlapped with the transparent region.

In second aspect, the present disclosure further provides a display device including the display panel described above.

### BRIEF DESCRIPTION OF DRAWINGS

FIG. 1 is a schematic diagram of an existing display panel.

FIG. 2 is a cross-sectional view of the existing display panel.

FIG. 3 is a schematic diagram of a pixel drive circuit in an existing display panel.

FIG. 4 illustrates a display panel according to an embodiment of the present disclosure.

FIG. 5 illustrates a heat conduction structure according to an embodiment of the present disclosure.

FIG. 6 illustrates another display panel according to an embodiment of the present disclosure.

FIG. 7 is a partial enlarged view of a display panel according to an embodiment of the present disclosure.

FIG. 8 is a partial cross-sectional view of the display panel shown in FIG. 7.

FIG. 9 is another partial cross-sectional view of the display panel shown in FIG. 7.

FIG. 10 illustrates another display panel according to an embodiment of the present disclosure.

FIG. 11 is another partial enlarged view of a display panel according to an embodiment of the present disclosure.

FIG. 12 is another cross-sectional view of a display panel according to an embodiment of the present disclosure.

FIG. 13 is a schematic diagram of an arrangement of a heat conduction structure according to an embodiment of the present disclosure.

FIG. 14 is a schematic diagram of another arrangement of a heat conduction structure according to an embodiment of the present disclosure.

FIG. 15 is a schematic diagram of another arrangement of a heat conduction structure according to an embodiment of the present disclosure.

FIG. 16 is a schematic diagram of another arrangement of a heat conduction structure according to an embodiment of the present disclosure.

FIG. 17 is a schematic diagram of another arrangement of a heat conduction structure according to an embodiment of the present disclosure.

FIG. 18 is a schematic diagram of a first drive circuit according to an embodiment of the present disclosure.

FIG. 19 is a schematic diagram of a display panel according to an embodiment of the present disclosure.

FIG. 20 is another partial enlarged view of a display panel according to an embodiment of the present disclosure.

FIG. 21 is a schematic diagram of an arrangement of a sensing component according to an embodiment of the present disclosure.

FIG. 22 is a schematic diagram of an arrangement of another sensing component according to an embodiment of the present disclosure.

FIG. 23 is a schematic diagram of a temperature conversion circuit according to an embodiment of the present disclosure.

FIG. 24 is a schematic diagram of a display panel according to an embodiment of the present disclosure.

### DETAILED DESCRIPTION

To make those skilled in the art better understand technical solutions of the present disclosure, the present disclosure is described in further detail below with reference to the accompanying drawings and specific implementations.

Unless otherwise defined, technical terms or scientific terms used in the present disclosure should have meanings as commonly understood by those of ordinary skills in the art to which the present disclosure pertains. The “first”, “second” and similar terms used in the present disclosure do not indicate any order, quantity, or importance, but are used only for distinguishing different components. Similarly, similar wordings such as “a”, “an” or “the” do not denote a limitation on quantity, but rather denote the presence of at least one. “Include”, “contain”, or similar wordings mean that elements or objects appearing before the wordings cover elements or objects listed after the wordings and their equivalents, but do not exclude other elements or objects. “Connect”, “join”, or a similar term is not limited to a physical or mechanical connection, but may include an electrical connection, whether direct or indirect. “Upper”, “lower”, “left”, “right”, etc., are used to represent relative positional relations, and when an absolute position of a described object is changed, the relative positional relation may also be correspondingly changed.

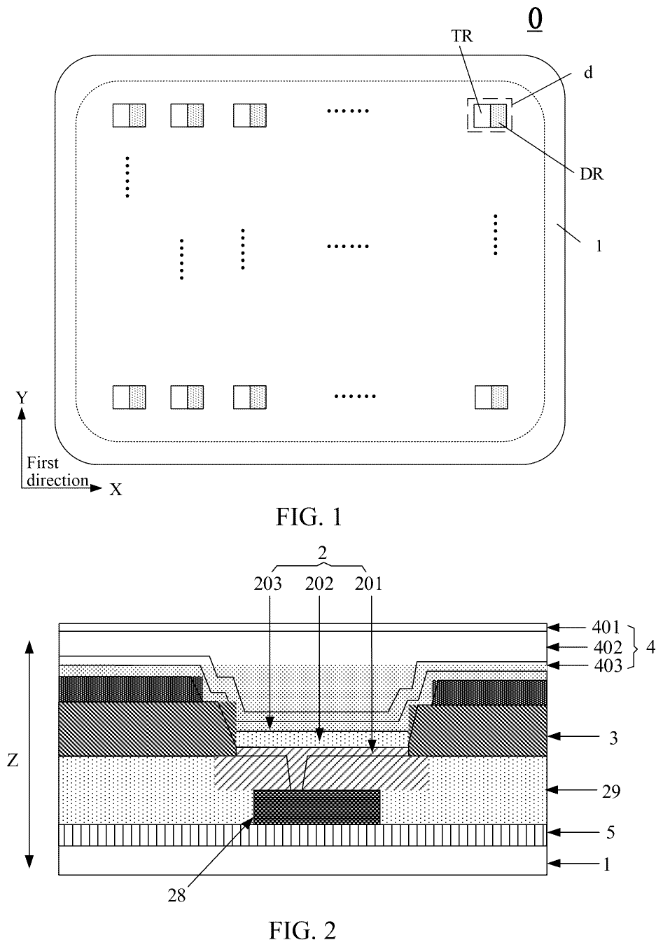

FIG. 1 illustrates an exemplary display panel 0 which can be applied in a glass window. Referring specifically to FIG. 1, the display panel 0 includes a display region DR and a transparent region TR. The display region DR includes at least one sub-pixel d, and each sub-pixel d is arranged in an array along a first direction X and a second direction Y respectively on a base substrate 1. The sub-pixel d includes at least one transparent light emitting device 2. In the exemplary display panel 0, since the transparent region TR is provided and the light emitting device 2 in the display region DR is a transparent light emitting device 2, the display panel 0 has high transparency and can be applied in a glass window.

FIG. 2 schematically illustrates a cross-sectional view of the sub-pixel d shown in FIG. 1 as shown in FIG. 2. The transparent light emitting device 2 in the exemplary sub-pixel d is described by taking a top-emission Organic Light Emitting Diode (OLED for short) as an example. Referring specifically to FIG. 2, the transparent light emitting device 2 includes, at least, a first electrode 201, a light emitting layer 202 and a second electrode 203 arranged sequentially in a direction facing away from the base substrate 1. In the exemplary transparent light emitting device 2, the first electrode 201 may be a reflective anode and the second electrode 203 may be a transmissive cathode. In the exemplary display panel 0, the reflective anode may be made of a metal material, such as any one or more of Magnesium (Mg), Argentum (Ag), Copper (Cu), Aluminum (Al), Titanium (Ti), and Molybdenum (Mo), or an alloy material of the above-mentioned metals, such as an Aluminum-Neodymium alloy (AlNd) or a Molybdenum-Niobium alloy (MoNb), and may be in a single-layer structure, or a multi-layer composite structure such as Ti/Al/Ti, or a stacked structure formed by a metal and a transparent conductive material, such as Indium Tin Oxide (ITO)/Ag/ITO, Mo/AlNd/ITO, and another reflective material. The transmissive cathode may be made of any one or more of Magnesium (Mg), Argentum (Ag), and Aluminum (Al), or an alloy made of any one or more of the above metals, or a transparent conductive material, such as Indium Tin Oxide (ITO), or may be of a multi-layer composite structure of a metal and a transparent conductive material. The light emitting layer 202 may include a small molecule organic material or a polymer molecule organic material (or may be a fluorescent light emitting material or a phosphorescent light emitting material). The light emitting layer 202 may emit red light, green light, blue light, white light or the like. In addition, according to practical requirements, the light emitting layer 202 may further include a functional layer such as an electron injection layer, an electron transport layer, a hole injection layer, a hole transport layer and the like in different examples.

Continuing with reference to FIG. 2, the sub-pixel d may further include a pixel drive circuit 28. In the exemplary display panel 0, since the exemplary display panel 0 is a transparent display panel 0, in order to ensure transparency of the transparent display panel 0, an orthographic projection of the anode on the base substrate 1 overlays an orthographic projection of the pixel drive circuit 28 on the base substrate 1, and the pixel drive circuit 28 and the anode are electrically connected to each other through an interlayer via hole. In some exemplary transparent display panels 0, the pixel drive circuit 28 may also be disposed in an opaque region outside the sub-pixel d and electrically connected to the transparent light emitting device 2 in the sub-pixel d through traces. The pixel drive circuit 28 may be disposed on a buffer layer 5 on the base substrate 1. Continuing with reference to FIG. 2, the exemplary sub-pixel d further includes a pixel definition portion 3, an interlayer insulating layer 29 disposed between the base substrate 1 and the anode, and an encapsulation layer 4. The encapsulation layer 4 includes a first sub-encapsulation layer 401, a second sub-encapsulation layer 402 and a third sub-encapsulation layer 403. The pixel definition portion 3 corresponds to one transparent light emitting device 2 and defines a light emitting region of the transparent light emitting device 2. Meanwhile, in order to ensure the transparency of the transparent display panel 0, the interlayer insulating layer 29 and the encapsulation layer 4 may be made of insulating materials of high transparency.

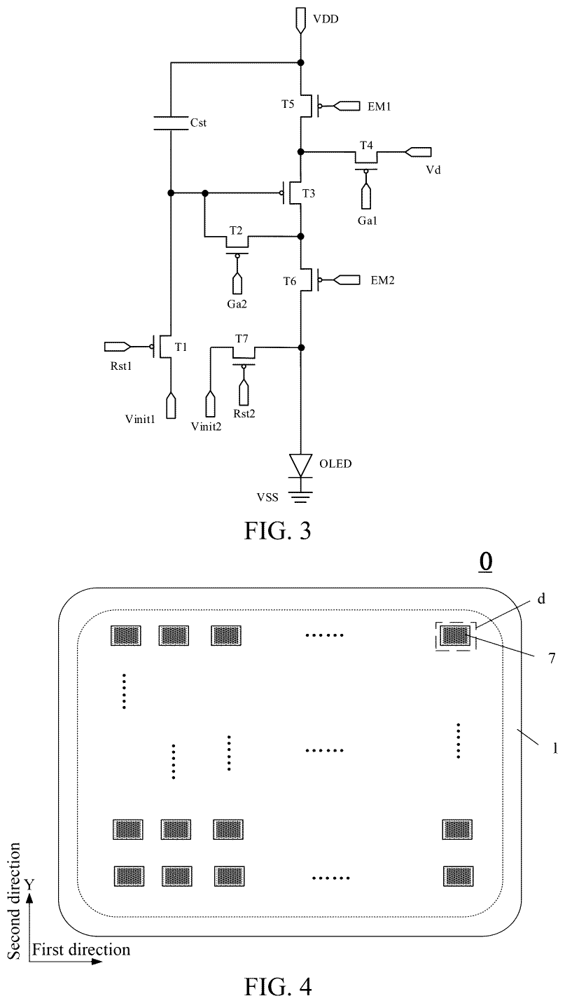

FIG. 3 is a circuit diagram of the pixel drive circuit 28 in the sub-pixel d shown in FIG. 2. The pixel drive circuit 28 may include a 7T1C (i.e. seven transistors and one capacitor) structure which includes, for example, a drive transistor T3, a data write transistor T4, a storage capacitor Cst, a threshold compensation transistor T2, a first reset transistor T1, a second reset transistor T7, a first light emitting control transistor T5 and a second light emitting control transistor T6. Referring to FIG. 3, a source of the data write transistor T4 is electrically connected to a source of the drive transistor T3, a drain of the data write transistor T4 is configured to be electrically connected to a data line Vd to receive a data signal, and a gate of the data write transistor T4 is configured to be electrically connected to a first scan signal line Ga1 to receive a scan signal. A first plate of the storage capacitor Cst is electrically connected to a first power supply voltage terminal VDD, and a second plate of the storage capacitor Cst is electrically connected to a gate of the drive transistor T3. A source of the threshold compensation transistor T2 is electrically connected to a drain of the drive transistor T3, a drain of the threshold compensation transistor T2 is electrically connected to a gate of the drive transistor T3, and a gate of the threshold compensation transistor T2 is configured to be electrically connected to a second scan signal line Ga2 to receive a compensation control signal. A source of the first reset transistor T1 is configured to be electrically connected to a first reset power supply terminal Vinit1 to receive a first reset signal, a drain of the first reset transistor T1 is electrically connected to the gate of the drive transistor T3, and a gate of the first reset transistor T1 is configured to be electrically connected to a first reset control signal line Rst1 to receive a first sub-reset control signal. A source of the second reset transistor T7 is configured to be electrically connected to a second reset power supply terminal Vinit2 to receive a first reset signal, a drain of the second reset transistor T7 is electrically connected to the first electrode 201 of the light emitting device 2, and a gate of the second reset transistor T7 is configured to be electrically connected to a second reset control signal line Rst2 to receive a second sub-reset control signal. A source of the first light emitting control transistor T5 is electrically connected to the first power supply voltage terminal VDD, a drain of the first light emitting control transistor T5 is electrically connected to the source of the drive transistor T3, and a gate of the first light emitting control transistor T5 is configured to be electrically connected to a first light emitting control signal line EM1 to receive a first light emitting control signal. A source of the second light emitting control transistor T6 is electrically connected to the drain of the drive transistor T3, a drain of the second light emitting control transistor T6 is electrically connected to the first electrode 201 of the light emitting device 2, and a gate of the second light emitting control transistor T6 is configured to be electrically connected to a second light emitting control signal line EM2 to receive a second light emitting control signal. The second electrode 203 of the light emitting device 2 is electrically connected to a second power supply voltage terminal VSS.

When the exemplary transparent display panel 0 is applied in a glass mounted in a vehicle, an operation of electronic devices in the transparent display panel 0 is easily affected due to a high temperature in a window during running of the vehicle, and in particular, a temperature of the transparent light emitting device 2 in the transparent display panel 0 is more easily increased due to an influence of light, resulting in a poor display effect of the transparent display panel 0. Meanwhile, an excessively high temperature in the window leads to permanent damage to the transparent display panel 0.

In view of the above problems, a display panel 0 and a display device are provided in the present disclosure.

As shown in FIG. 4, a display panel 0 is provided in the present disclosure. The display panel 0 may be applied in a glass window. The display panel 0 includes a base substrate 1 and a plurality of sub-pixels d provided on the base substrate 1. Each sub-pixel d includes at least one light emitting device 2. The light emitting device 2 includes a first electrode 201, a light emitting layer 202 and a second electrode 203 disposed in sequence in a direction facing away from the base substrate 1. The display panel 0 further includes a heat conduction structure 7, the heat conduction structure 7 is disposed on a side of the first electrode 201 facing away from the light emitting layer 202, and orthographic projections of the heat conduction structure 7 and the first electrode 201 on the base substrate 1 are at least partially overlapped.

In an embodiment of the present disclosure, as shown in FIG. 4, the display panel 0 includes a plurality of sub-pixels d disposed in an array on the base substrate 1, and each sub-pixel d includes at least one light emitting device 2. The display panel 0 further includes a heat conduction structure 7 configured to transfer heat from the light emitting device 2 outside the display panel 0. Specifically, as shown in FIG. 4, the heat conduction structure 7 is disposed on the side of the first electrode 201 of the light emitting device 2 facing away from the light emitting layer 202, and the orthographic projections of the heat conduction structure 7 and the first electrode 201 on the base substrate 1 are at least partially overlapped. In this way, the heat conduction structure 7 directly transfer the heat from the light emitting device 2 outside the display panel 0, thereby avoiding affecting operation of the light emitting device 2 or damaging the light emitting device 2 when the temperature of the display panel 0 is high. In some embodiments, the heat conduction structure 7 is attached to the anode of the light emitting device 2 on a side of the anode of the light emitting device 2 facing away from the light emitting layer 202. In this way, the light emitting device 2 directly transfers heat to the heat conduction structure 7. A large contact area between the light emitting device 2 attached to the heat conduction structure 7 leads to that heat from the light emitting device 2 is more effectively transferred to the heat conduction structure 7. In this embodiment, in order to maximize a heat conduction efficiency of the heat conduction structure 7, the orthographic projection of the heat conduction structure 7 on the base substrate 1 covers the orthographic projection of the first electrode 201 of the light emitting device 2 on the base substrate 1. It should be noted that the light emitting device 2 may be an Organic Light Emitting Diode (OLED for short), in which case the light emitting device 2 may be a top-emission OLED or a bottom-emission OLED, and the light emitting device 2 being a top-emission OLED is described merely as an example in an embodiment of the present disclosure. In this case, the first electrode 201 may be an anode and the second electrode 203 may be a cathode.

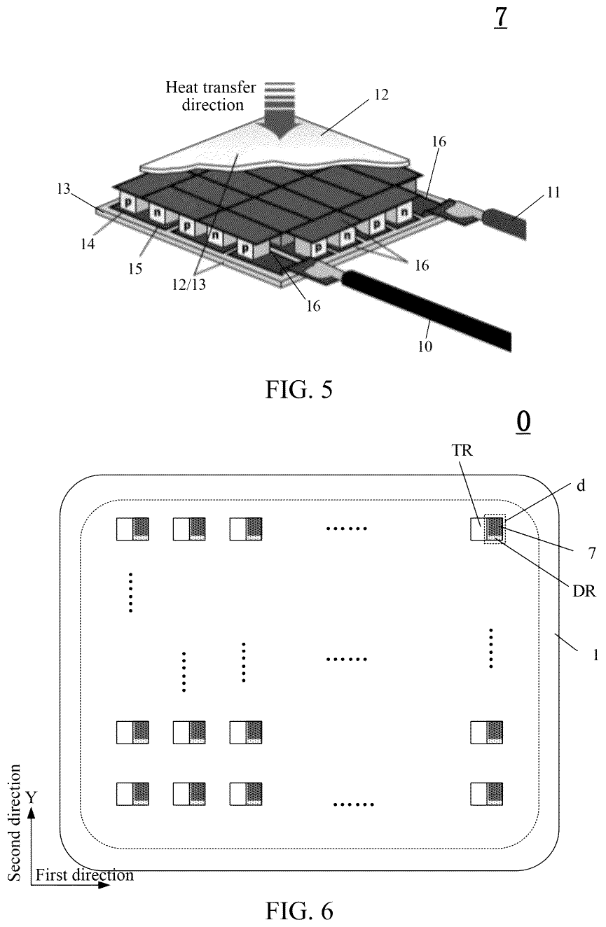

In some embodiments, the display panel 0 further includes a heat dissipation structure 6 disposed in a direction facing away from the heat conduction structure 7. In an embodiment of the present disclosure, the heat conduction structure 7 is configured to transfer heat emitted by the light emitting device 2 through the heat dissipation structure 6 under control of a first control signal. Referring specifically to FIG. 5, FIG. 5 is a schematic diagram of a heat conduction structure 7 in an embodiment of the present disclosure. As illustrated in FIG. 5, the heat conduction structure 7 includes a first heat conduction sheet 12 a second heat conduction sheet 13 and a semiconductor layer disposed between the first heat conduction sheet 12 and the second heat conduction sheet 13. Two different conductive electrodes 16 in the semiconductor layer are connected to a first control signal line 10 and a second control signal line 11 respectively. The first heat conduction sheet 12 and the second heat conduction sheet 13 are insulated from the first control signal line 10 and the second control signal line 11 respectively. In an embodiment of the present disclosure, the semiconductor layer is disposed in a same layer as the first control signal line 10 and the second control signal line 11. The semiconductor layer further includes a plurality of first semiconductors 14 and second semiconductors 15, and the first semiconductors 14 and the second semiconductors are disposed alternately. Each of the first semiconductors 14 is connected to one of the second semiconductors 15 in series through one conductive electrode 16. Both the first semiconductors 14 and the second semiconductors 15 are in contact with the first heat conduction sheet 12 and the second heat conduction sheet 13 directly. In an embodiment of the present disclosure, when a signal between the first control signal line 10 and the second control signal line 11 is the first control signal, the semiconductor layer transfers heat from a side of the first heat conduction sheet 12 to a side of the second heat conduction sheet 13 such that a temperature of the first heat conduction sheet 12 is lower than a temperature of the second heat conduction sheet 13. In the embodiment of the present disclosure, the first heat conduction sheet 12 in the heat conduction structure 7 faces the anode of the light emitting device 2, and the second heat conduction sheet 13 in the heat conduction structure 7 faces the heat dissipation structure 6 and is connected to the heat dissipation structure 6. Therefore, the heat conduction structure 7 can transfer the heat of the light emitting device 2 from the side of the first heat conduction sheet 12 of the heat conduction structure 7 to the side of the second heat conduction sheet 13 of the heat conduction structure 7 under the control of the first control signal, and then transfer the heat outside the display panel 0 through the heat dissipation structure 6 connected to the second heat conduction sheet 13. In this way, heat dissipation of the light emitting device 2 in the display panel 0 is achieved.

It should be noted that, in some embodiments, the heat dissipation structure 6 may be made of a copper alloy material, one side of the heat dissipation structure 6 is connected to a hot end of the heat conduction structure 7, and another side of the heat dissipation structure 6 is connected to a high thermal conductivity material outside the display panel 0. In an embodiment of the present disclosure, the material of the heat dissipation structure 6 may be another heat conduction material with high thermal conductivity, and the high thermal conductivity material outside the display panel 0 may be a metal structure outside the display panel 0, which is not limited in the embodiment of the present disclosure. Likewise, in some embodiments, materials of the first semiconductor 14 and the second semiconductor 15 may be a ternary solid solution alloy based on bismuth telluride, for example, the first semiconductor 14 may be Bi₂Te₃—Bi₂Se₃, and the material of the second semiconductor 15 may be Bi₂Te₃—Sb₂Te₃. It should be noted that the materials of the first semiconductor 14 and the material of the second semiconductor 15 being the above materials is described merely as an example in the embodiment of the present disclosure.

In some embodiments, FIG. 6 illustrates another display panel 0 according to an embodiment of the present disclosure. As shown in FIG. 6, the display panel 0 may be a transparent display panel 0. The transparent display panel 0 includes a display region DR and a transparent region TR. The display region DR includes at least one sub-pixel d, and the transparent region TR is a non-luminous region. The sub-pixel d includes at least one light emitting device 2, and the at least one light emitting device 2 may be the light emitting device 2 as shown in FIGS. 1-3. The light emitting device 2 includes an anode, a light emitting layer 202 and a cathode in a direction facing away from a base substrate 1. In an embodiment of the present disclosure, one light emitting device 2 may display any one color of red R, green G, blue B, or white W. In the transparent display panel 0 shown in FIG. 6, in order to ensure transparency of the transparent display panel 0, an area of the transparent region TR is larger than or equal to an area of the display region DR. In some embodiments, orthographic projections of the heat conduction structure 7 and the transparent region TR on the base substrate 1 do not overlap, thereby further improving the transparency of the transparent display panel 0. It should be noted that the display panel 0 shown in FIG. 6 is only an exemplary transparent display panel 0 according to an embodiment of the present disclosure, and transparent display panels 0 with other structures are also within the protection scope of the present disclosure.

In an embodiment of the present disclosure, with continued reference to FIG. 6, since the heat conduction structure 7 is disposed on a side of the anode of the light emitting device 2 facing away from the light emitting layer 202, and the orthographic projection of the heat conduction structure 7 on the base substrate 1 is at least partially overlapped with an orthographic projection of the anode of the light emitting device 2 on the base substrate 1, while in the transparent display panel 0, an anode of a light emitting device 2 in the display region DR may have an opaque structure. Therefore, in this way, the heat conduction structure 7 is disposed between the opaque structure in the display region DR and the base substrate 1, so that the area of the transparent region TR in the transparent display panel 0 is not occupied. In this way, light transmittance of the transparent display panel 0 is not affected, and an aperture ratio of the sub-pixel d is not affected by blocking light emission of the sub-pixel d in the display region DR. On the basis of not affecting a display effect of the transparent display panel 0, cooling of the transparent display panel 0 is achieved.

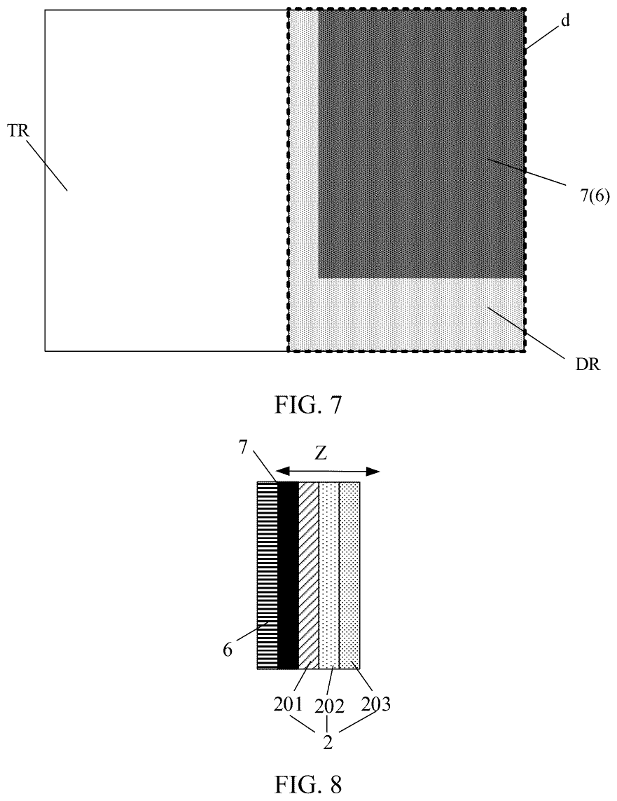

In some embodiments, FIG. 7 is a partial enlarged view of the display panel 0 shown in FIG. 6 according to the embodiment of the present disclosure. As shown in FIG. 7, the heat conduction structures 7 and the light emitting devices 2 are disposed in one-to-one correspondence. The first heat conduction sheet 12 in each heat conduction structure 7 is connected to a heat dissipation structure 6, and the second heat conduction sheet 13 in the heat conduction structure 7 is directly connected to an anode of a light emitting device 2. In the embodiment of the present disclosure, since the first heat conduction sheet 12 in the heat conduction structure 7 is directly connected with the heat dissipation structure 6, and the second heat conduction sheet 13 in the heat conduction structure 7 is directly connected to the anode of the light emitting device 2, the heat conduction structure 7 is in direct contact with the light emitting device 2 and the heat dissipation structure 6 respectively, which brings a better heat dissipation effect. Reference specifically to FIG. 8, FIG. 8 is a partial cross-sectional view of the display panel 0 shown in FIG. 7. As shown in FIG. 8, in an embodiment of the present disclosure, the second heat conduction sheet 13 in the heat conduction structure 7 is directly attached to the heat dissipation structure 6, and the first heat conduction sheet 12 in the heat conduction structure 7 is directly attached to the anode of the light emitting device 2. In this way, the light emitting device 2 directly transfers heat to the heat conduction structure 7. Since the light emitting device 2 and the heat conduction structure 7 are connected by attachment, a large contact area between the light emitting device 2 and the heat conduction structure 7 leads to that heat from the light emitting device 2 is more effectively transferred to the heat conduction structure 7. In this embodiment, in order to further improve the heat conduction efficiency of the heat conduction structure 7, the orthographic projection of the heat conduction structure 7 on the base substrate 1 covers the orthographic projection of the anode of the light emitting device 2 on the base substrate 1, and the orthographic projection of the heat dissipation structure 6 on the base substrate 1 covers the orthographic projection of the heat conduction structure 7 on the base substrate 1. In this way, the contact area is maximized so that the heat conduction efficiency of the heat conduction structure 7 is further improved.

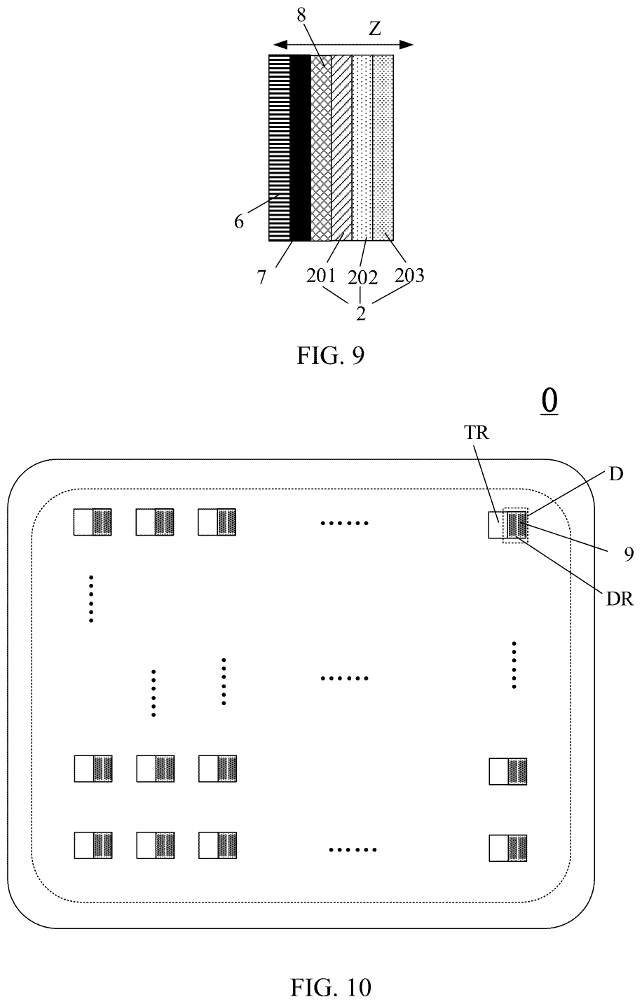

In some embodiments, as shown in FIG. 9, FIG. 9 is another partial cross-sectional view of the display panel 0 shown in FIG. 7. The second heat conduction sheet 13 in the heat conduction structure 7 is connected to the heat dissipation structure 6, and an insulating heat conduction layer 8 is provided directly between the first heat conduction sheet 12 in the heat conduction structure 7 and the anode of the light emitting device 2. In the embodiment of the present disclosure, since the second heat conduction sheet 13 in the heat conduction structure 7 is directly connected to the heat dissipation structure 6, and the first heat conduction sheet 12 in the heat conduction structure 7 and the anode of the light emitting device 2 are connected to each other through the insulating heat conduction layer 8, the heat conduction structure 7 and the light emitting device 2 carry out heat transmission through the insulating heat conduction layer 8 only, which brings a better heat dissipation effect. In the embodiment of the present disclosure, as shown in FIG. 9, the second heat conduction sheet 13 in the heat conduction structure 7 is directly attached to the heat dissipation structure 6, the first heat conduction sheet 12 in the heat conduction structure 7 is attached to a side of the insulating heat conduction layer 8, and another side of the insulating heat conduction layer 8 is directly attached to the anode of the light emitting device 2. Since the light emitting device 2 and the heat conduction structure 7 are connected by attachment, a large contact area between the light emitting device 2 and the heat conduction structure 7 leads that heat from the light emitting device 2 is more effectively transferred to the heat conduction structure 7. In this embodiment, in order to maximize the heat conduction efficiency of the heat conduction structure 7, the orthographic projection of the heat conduction structure 7 on the base substrate 1 covers the orthographic projection of the anode of the light emitting device 2 on the base substrate 1, and the orthographic projection of the heat dissipation structure 6 on the base substrate 1 covers the orthographic projection of the heat conduction structure 7 on the base substrate 1. In this way, the contact area is maximized so that the heat conduction efficiency of the heat conduction structure 7 is further improved.

Meanwhile, the insulating heat conduction layer 8 can electrically insulate the anode of the light emitting device 2 from the first heat conduction sheet 12 in the heat conduction structure 7, avoiding the heat conduction structure 7 from affecting an electrical signal of the anode of the light emitting device 2. In the embodiment of the present disclosure, since the heat conduction structure 7 is avoided from affecting the electrical signal of the anode of the light emitting device 2, one heat conduction structure 7 can be provided corresponding to a plurality of light emitting devices 2, that is, one heat conduction structure 7 dissipates heat for the plurality of light emitting devices 2. As shown in FIG. 10, in some embodiments, the display panel 0 is divided into a plurality of pixel units D, each pixel unit D includes a plurality of sub-pixels d, and at least part of respective heat conduction structures 7 in each pixel unit D is an integral structure.

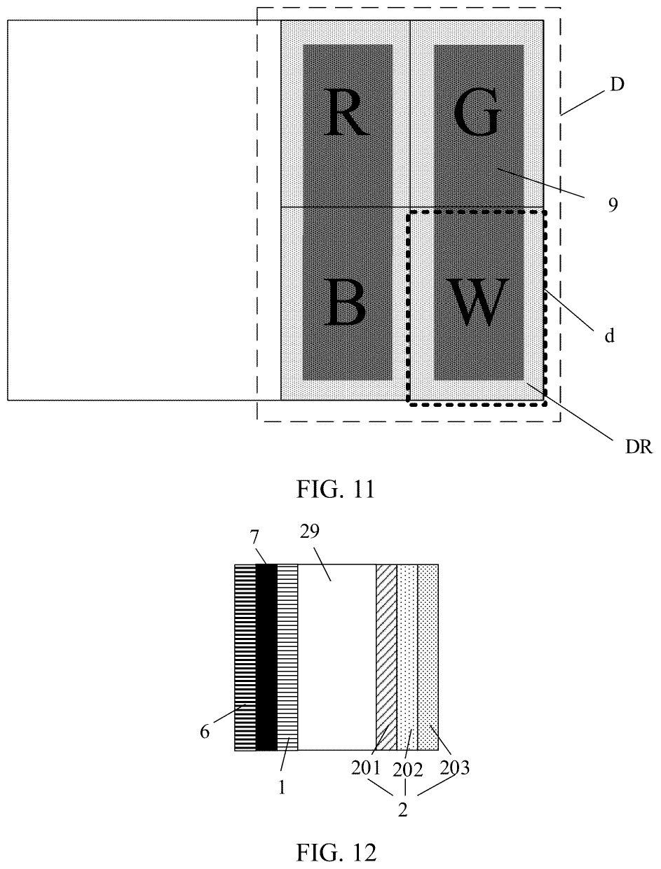

Continuing with reference to FIG. 10, the display panel 0 includes the base substrate 1 and the plurality of pixel units D disposed on the display substrate. Each pixel unit D includes at least one sub-pixel d, each sub-pixel d includes at least one light emitting device 2. Referring specifically to FIG. 11, FIG. 11 is a partial enlarged view of the display panel 0 shown in FIG. 10. As shown in FIG. 11, one pixel unit D including four sub-pixels d is described as an example, wherein the four sub-pixels d display red R, green G, blue B, and white W respectively. Sub-pixels d in each pixel unit D are distributed in the display region DR of the display panel 0, and the sub-pixels d are arranged in an array in the pixel unit D along a first direction X and a second direction Y respectively. It should be noted that the sub-pixels d in the pixel unit D including sub-pixels d in other colors and the sub-pixels d in the pixel unit D arranged in other arrangement modes are within the protection scope of the present disclosure.

Continuing with reference to FIG. 11, since one pixel unit D includes four sub-pixels d in the embodiment of the present disclosure, one pixel unit D corresponds to four heat conduction structures 7. As shown in FIG. 11, the four heat conduction structures 7 are respectively combined in pairs to form first heat conduction structures 9 of an integral structure. That is, one pixel unit D substantially corresponds to only two first heat conduction structures 9. In the embodiment of the present disclosure, the second heat conduction sheets 13 in each first heat conduction structure 9 are connected to corresponding heat dissipation structures 6, and an insulating heat conduction layer 8 is provided directly between the first heat conduction sheets 12 in the heat conduction structure 9 and the anode of the light emitting device 2. In the embodiment of the present disclosure, since the second heat conduction sheets 13 in the first heat conduction structure 9 are directly connected to the heat dissipation structures 6, and the first heat conduction sheets in the first heat conduction structure 9 and the anode of the light emitting device 2 are connected to each other through the insulating heat conduction layer 8, the heat conduction structures 7 and the light emitting device 2 carry out heat transmission through the insulating heat conduction layer 8 only, which brings a better heat dissipation effect. Meanwhile, the insulating heat conduction layer 8 avoids anodes of different light emitting devices 2 corresponding to a same first heat conduction structure 9 from electrically connecting to each other through the first heat conduction structure 9, which affects display of the display panel 0.

In some embodiments, the second heat conduction sheets 13 in the first heat conduction structure 9 are directly attached to corresponding heat conduction structures 7, the first heat conduction sheets 12 in the first heat conduction structure 9 are attached to a side of the insulating heat conduction layer 8, and another side of the insulating heat conduction layer 8 is directly attached to the anode of the light emitting device 2. In this way, the light emitting device 2 directly transfers heat to the first heat conduction structure 9 through the insulating heat conduction layer 8. Since the light emitting device 2 and the first heat conduction structure 9 are connected by attachment, a large contact area between the light emitting device 2 and the first heat conduction structure 9 leads to that heat from the light emitting device 2 is more effectively transferred to the first heat conduction structure 9. Meanwhile, it should be noted that since one pixel unit D includes four sub-pixels d in the embodiment of the present disclosure, one pixel unit D corresponding to four heat conduction structures 7 combined in pairs to form first heat conduction structures 9 is described as an example in the embodiment of the present disclosure. In some embodiments, a first heat conduction structure 9 in which three of the above four heat conduction structures 7 are combined into an integral structure and a first heat conduction structure 9 in which four of the above four heat conduction structures 7 are combined into an integral structure are also within the protection scope of the present disclosure.

In some embodiments, in the display panel 0 as shown in FIGS. 4-11, both the heat conduction structure 7 and the heat dissipating structure 6 are disposed on a side of the base substrate 1 close to the anode of the light emitting device 2. In an embodiment of the present disclosure, the heat conduction structure 7 and the heat dissipation structure 6 may be disposed in a film structure of the display panel 0 when the display panel 0 is manufactured. In this way, the display panel 0 having the heat conduction structure 7 has a higher integration, which is convenient to thinning design of the display panel 0. Meanwhile, a positional relationship between the heat conduction structure 7 and the anode of the light emitting device 2 can be easily set. That is, during manufacturing, the orthographic projections of the heat conduction structure 7 and the anode of the light emitting device 2 on the base substrate 1 can be easily overlapped with each other at least partially, so as to improve a yield of the transparent display panel 0.

Likewise, in some embodiments, as shown in FIG. 12, the heat conduction structure 7 may also be disposed on the side of the base substrate 1 facing away from the light emitting device 2. Meanwhile, as shown in FIG. 12, the first heat conduction sheet 12 in the heat conduction structure 7 is connected to the base substrate 1, and the second heat conduction sheet 13 in the heat conduction structure 7 is connected to the heat dissipation structure 6, thus facilitating mounting the heat conduction structure 7.

Meanwhile, in an embodiment of the present disclosure, the first heat conduction sheet 12 in the heat conduction structure 7 may also be directly attached to the base substrate 1, and the second heat conduction sheet 13 in the heat conduction structure 7 may be directly attached to the heat dissipation structure 6. In this way, since the transparent display panel 0 and the heat conduction structure 7 are connected by attachment, a large contact area between the light emitting device 2 and the heat conduction structure 7 leads to that heat from the light emitting device 2 is more effectively transferred to the heat conduction structure 7.

In the embodiment of the present disclosure, after manufacturing of the display substrate having the light emitting device 2 is completed, a thin film including the heat conduction structure 7 may be attached to the side facing away from the base substrate 1, and the orthographic projections of the heat conduction structure 7 and the anode of the light emitting device 2 on the base substrate 1 can be at least partially overlapped. In this way, without adjusting the manufacturing process of the display panel 0, the temperature of the display panel 0 can be lowered while the light transmittance of the display panel 0 is not affected.

In some embodiments, in the transparent display panel 0, the heat conduction structure 7 may also be disposed on the side of the base substrate 1 close to the anode of the light emitting device 2, and the heat dissipating structure 6 may be disposed on the side of the base substrate 1 facing away from the anode of the light emitting device 2. In the embodiment of the present disclosure, the first heat conduction sheet 12 in the heat conduction structure 7 is connected to the anode of the light emitting device 2, and the second heat conduction sheet 13 in the heat conduction structure 7 is connected to the heat dissipation structure 6.

In some embodiments, the display panel 0 further includes a plurality of first display signal lines. Orthographic projections of the first control signal line 10 and the second control signal line 11 on the base substrate 1 are overlapped with an orthographic projection of the first display signal lines on the base substrate 1 respectively, and the orthographic projections of the first control signal line 10 and the second control signal line 11 on the base substrate 1 are not overlapped. In the embodiment of the present disclosure, when the display panel 0 is the transparent display panel 0 as shown in FIGS. 4-12, the first control signal line 10 and the second control signal line 11 for controlling operation of the heat conduction structure 7 can be designed to be overlapped with the orthographic projection of the first display signal lines on the display substrate on the base substrate 1 respectively, so as to avoid the first control signal line 10 and second control signal line 11 additionally provided from affecting the light transmittance and a pixel aperture ratio of the transparent display panel 0. Specifically, in the transparent display panel 0, the existing first control signal line 10 on the transparent display panel 0 may have an opaque structure, so that the first control signal line 10 and the second control signal line 11 are arranged between the opaque structure of the display panel 0 and the base substrate 1. In this manner, an area of a light-transmitting area in the transparent display panel 0 is not occupied greatly, the light transmittance of the transparent display panel 0 is not affected, and light emission of the sub-pixels d in the display region DR is not blocked, which affects the pixel aperture ratio. It should be noted that the first display signal lines may be any type of signal line in the display panel 0 for driving the sub-pixels d to display an image, for example, a gate signal line, a data signal line or a power signal line, which is not limited in the embodiment of the present disclosure.

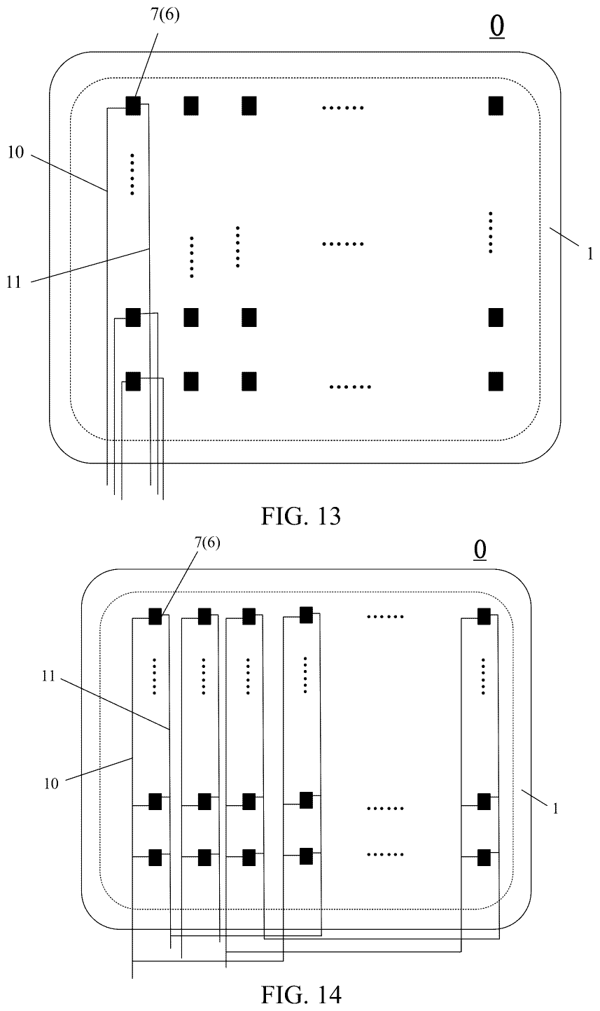

In some embodiments as shown in FIG. 13, FIG. 13 illustrates an exemplary arrangement of the heat conduction structures 7 in the display panel 0. In the embodiment of the present disclosure, the heat conduction structures 7 are arranged in an array on the side of the base substrate 1 close to the first electrode 201, and the first control signal line 10 and the second control signal line 11 connected to a single heat conduction structure 7 are located on two opposite sides of the heat conduction structure 7 respectively. In this way, wiring of the signal lines in the display panel 0 is more uniform, and interference of the first control signal lines 10 and the second control signal lines 11 on the signal lines in the display panel 0 is avoided.

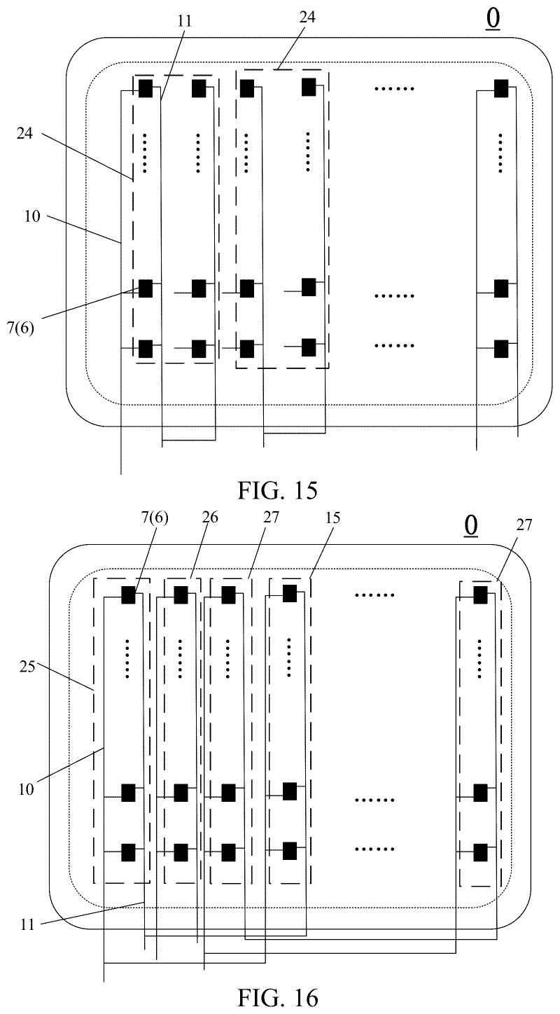

In some embodiments as shown in FIG. 14, FIG. 14 illustrates another exemplary arrangement of the heat conduction structures 7 in the display panel 0. A plurality of heat conduction structures 7 are arranged in sequence in a column direction. Heat conduction structures 7 located in a same column are connected to a single first control signal line 10 and a single second control signal line 11. As shown in FIGS. 15-17, heat conduction structures 7 in columns are divided into a plurality of heat conduction structure groups 24, and the heat conduction structures 7 in different groups are different. A first control signal line 10 to which heat conduction structures 7 in a heat conduction structure group 24 are connected is shorted, and a second control signal line 11 to which heat conduction structures 7 in a heat conduction structure group 24 are connected is shorted.

Specifically, refer to FIG. 15. In the embodiment of the present disclosure, the heat conduction structures 7 are divided into a plurality of heat conduction structure groups 24 in a column direction of the heat conduction structures 7, and the heat conduction structures 7 in different groups are different. Heat conduction structures 7 in a single heat conduction structure group 24 are connected to a single first control signal line 10 and a single second control signal line 11. In this way, the heat conduction structures 7 are driven in group. On one hand, quantities of the first control signal lines 10 and the second control signal lines 11 required in the embodiment of the present disclosure is significantly reduced as compared to a case where each heat conduction structure 7 is connected with one first control signal line 10 and the second control signal line 11 respectively. Meanwhile, a drive circuit for driving the first control signal line 10 and the second control signal line 11 is significantly simplified. On the other hand, different driving voltages may be applied to different heat conduction structure groups 24, leading to a better heat dissipation effect of the display panel 0.

In some embodiments, reference is made to FIG. 16, which illustrates another way of grouping in an embodiment of the present disclosure. Each column of heat conduction structures 7 is divided into three heat conduction structure groups 24. The heat conduction structures 7 in different heat conduction structure groups 24 are different from each other, and every three columns of heat conduction structures 7 are located in the three different heat conduction structure groups 24 in sequence. Specifically, in an embodiment of the present disclosure, each column of heat conduction structures 7 is divided into a first heat conduction structure group 25, a second heat conduction structure group 26 and a third heat conduction structure group 27. The display panel 0 includes N columns of heat conduction structures 7 and the heat conduction structures 7 in the N columns are arranged in sequence in the row direction. Every three columns of heat conduction structures 7 are located in sequence in three different heat conduction structure groups 24, that is, the first heat conduction structure group 25 includes a first, a fourth, a seventh . . . and an (N−2)-th columns of heat conduction structures 7, the second heat conduction structure group 26 includes a second, a fifth, an eighth . . . and an (N−1)-th columns of heat conduction structures 7, and the third heat conduction structure group 27 includes a third, a sixth, a ninth . . . and an N-th columns of heat conduction structures 7. Thus, only three first control signals are required for the heat conduction structures 7 in the display panel 0 to drive all the heat conduction structures 7 in the display panel 0. Meanwhile, the heat conduction structures 7 in such a driving mode by group have a better heat dissipation effect.

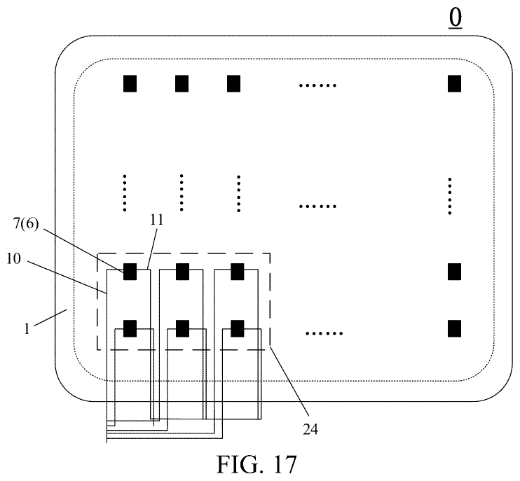

In some embodiments, as shown in FIG. 17, FIG. 17 illustrates another way of grouping according to an embodiment of the present disclosure. The heat conduction structures 7 are divided into a plurality of heat conduction structure groups 24 arranged in an array. A first control signal line 10 to which heat conduction structures 7 in a heat conduction structure group 24 are connected is shorted, and a second control signal line 11 to which heat conduction structures 7 in a heat conduction structure group 24 are connected is shorted. In an embodiment of the present disclosure, reference is made specifically to FIG. 17. In this way, on one hand, quantities of the first control signal lines 10 and the second control signal lines 11 required in the embodiment of the present disclosure is significantly reduced as compared to a case where each heat conduction structure 7 is connected with one first control signal line 10 and the second control signal line 11 respectively. Meanwhile, a drive circuit for driving the first control signal lines 10 and the second control signal lines 11 is significantly simplified. On the other hand, different driving voltages may be applied to heat conduction structure groups 24 in different regions, which leads to a better heat dissipation effect of the display panel 0.

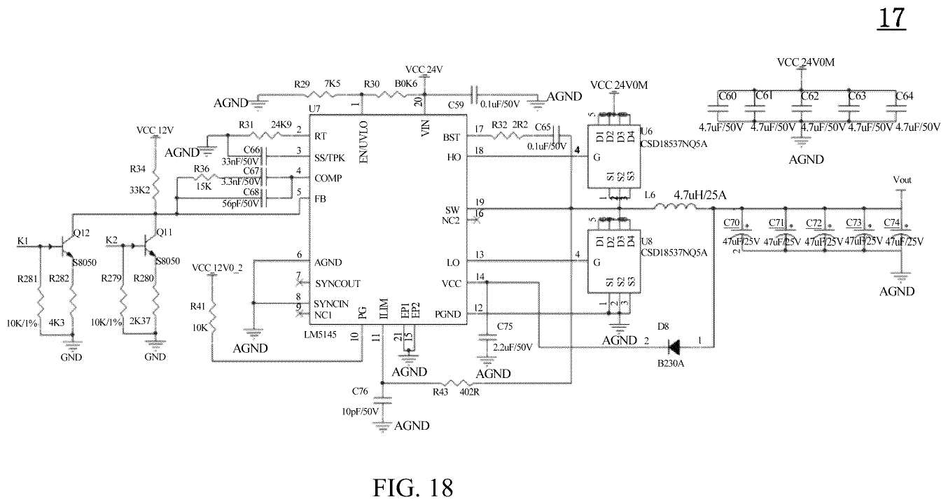

In some embodiments, the display panel 0 further includes a first drive circuit 17. The first drive circuit 17 is configured to provide a first control signal to the heat conduction structure 7 according to the temperature of the display panel 0. In some embodiments, the first drive circuit 17 may be a switching power supply circuit or other DC drive circuit, and the first drive circuit 17 being a switching power supply circuit is described as an example in the embodiment of the present disclosure. Specifically, as shown in FIG. 18, FIG. 18 illustrates an exemplary switching power supply circuit including a first power supply control terminal K1, a second power supply control terminal K2, a signal output terminal Vout, a drive sub-circuit, and a peripheral circuit of the drive sub-circuit. In an embodiment of the present disclosure, the drive sub-circuit may be a switching power supply chip LM5145. When the first drive circuit 17 is operating, power supply control signals are written into the first power supply control terminal K1 and the second power supply control terminal K2, and the switching power supply chip LM5145 outputs corresponding first control signals to the signal output terminal Vout according to the power supply control signals written to the first power supply control terminal K1 and the second power supply control terminal K2. In the embodiment of the present disclosure, the first power supply control terminal K1 and the second power supply control terminal K2 may be connected to a first controller 18 so that the first drive circuit 17 may output an adjustable first control signal according to a change of the power supply control signal output by the first controller 18. Therefore, the adjustable first control signal can be written to the heat conduction structures 7, that is, a thermal conductivity of the heat conduction structures 7 can be changed according to a change of the first control signal. In this way, the heat conduction structures 7 can adjust their thermal conductivity as required.

It should be noted that, the switching power supply chip LM5145 being the drive sub-circuit is described merely as an example in the embodiment of the present disclosure, and a drive sub-circuit using other chips is also within the protection scope of the present disclosure. Likewise, the first drive circuit 17 shown in FIG. 18 may further include a plurality of power supply control terminals and a signal output terminal Vout. A first drive circuit 17 including the first power supply control terminal K1, the second power supply control terminal K2 and the signal output terminal Vout is described merely as an example in the present disclosure. The first drive circuit 17 may further include a plurality of power supply control terminals and a plurality of signal output terminals Vout, which are also within the protection scope of the present application.

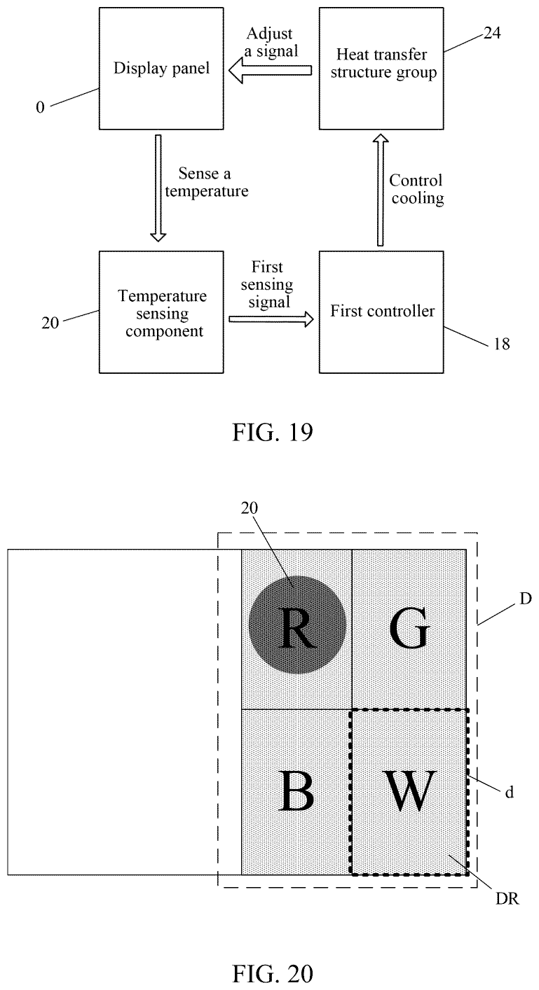

In some embodiments, as shown in FIGS. 19 and 20, the display panel 0 further includes a temperature sensing component 20 and the first controller 18. The temperature sensing component 20 is disposed on a side of the first electrode 201 facing away from the light emitting layer 202, and orthographic projections of the temperature sensing component 20 and the first electrode 201 on the base substrate 1 at least partially overlap with each other. The temperature sensing component 20 is configured to generate a first sensing signal according to the temperature of the display panel 0. The first controller 18 is configured to control the operation of the heat conduction structure 7 according to the first sensing signal.

In an embodiment of the present disclosure, the temperature sensing component 20 is disposed on a side of the anode of the light emitting device 2 facing away from the light emitting layer 202, and orthographic projections of the temperature sensing component 20 and the anode of the light emitting device 2 on the base substrate 1 at least partially overlap with each other. Therefore, when the display panel 0 is a transparent display panel 0, since the anode of the light emitting device 2 in the transparent display panel 0 can be in an opaque structure, heat dissipation structures are disposed between the opaque structure of the display panel 0 and the base substrate 1 in this manner, so that the area of the light transmitting area in the transparent display panel 0 is not occupied greatly, the light transmittance of the transparent display panel 0 is not affected, and the light emission of the sub-pixels d in the display region DR is not blocked, which affects the pixel aperture ratio. The heat conduction structure 7 is controlled to cool the display panel 0 by providing the temperature sensing component 20 and the first controller 18 without affecting the display effect of the transparent display panel 0.

Specifically, the temperature sensing component 20 may generate the first sensing signal according to the temperature of the display panel 0. The first controller 18 may receive the first sensing signal through an analog-to-digital conversion sub-circuit and process the first sensing signal. In some embodiments, when the first controller 18 determines that the temperature of the display panel 0 exceeds a preset value according to the first sensing signal, that is, when the temperature of the display panel 0 is determines to be excessively high, the first controller 18 outputs a first control signal to control the heat dissipation structures on the display panel 0 to dissipate the light emitting device 2 on the display panel 0, so as to reduce the temperature of the display panel 0 and avoid affecting operation of the display panel 0 or causing damages to the display panel 0 due to the excessively high temperature.

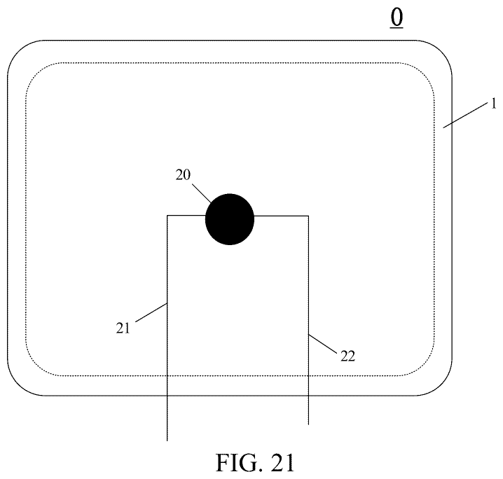

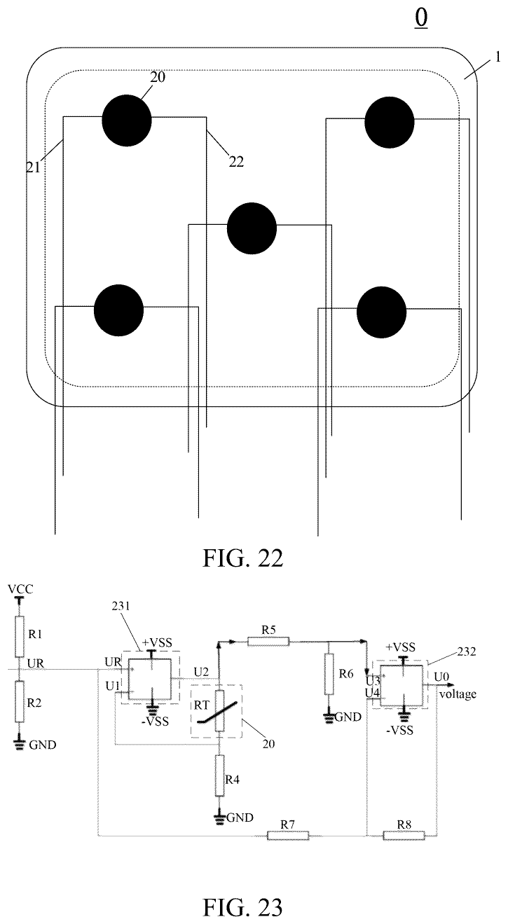

In some embodiments, the quantity of the temperature sensing component(s) 20 in the display panel 0 may be one or more. Referring specifically to FIG. 21, when the quantity of the temperature sensing component 20 is one, since a temperature in a central region of the display panel 0 is the highest, the temperature sensing component 20 is provided in the central region of the display panel 0, so that it is possible to more accurately determine whether the light emitting device 2 in the display panel 0 needs heat dissipation, and to more accurately sense the temperature of the display panel 0. When the quantity of the temperature sensing component 20 is plural as shown in FIG. 22, the temperature sensing component 20 may be uniformly arranged in the display panel 0. In this manner, a plurality of first sensing signals can be generated according to temperatures in different regions of the display panel 0. In this embodiment, the first controller 18 may process a plurality of first sensing signals through a preset temperature control algorithm to make temperature sensing of the display panel 0 more accurate.

In some embodiments, the display panel 0 further includes a temperature conversion circuit 23. The temperature conversion circuit 23 is configured to convert the first sensing signal into an electrical signal and transmit the signal to the first controller 18. In the embodiment of the present disclosure, in this manner, the temperature on the display panel 0 can be sensed by providing only a temperature sensing component 20 having a relatively simple structure. Therefore, the display panel 0 is simple in structure and easy to realize, which facilitates a thinning design.

Specifically, as shown in FIG. 23, FIG. 23 illustrates an exemplary temperature conversion circuit 23. In some embodiments, the temperature sensing component 20 at least includes at least one of a thermistor or a thermocouple. The temperature conversion circuit 23 shown in FIGS. 21-23 is described only by taking a thermal sensitive module as the temperature sensing module 20 as an example. Referring specifically to FIGS. 21-23, a thermistor is provided on the display panel 0, and one end of a first sensing signal line 21 and one end of a second sensing signal line 22 are connected to the thermistor respectively, and another end of a first sensing signal line 21 and another end of a second sensing signal line 22 are connected to the temperature conversion circuit 23 respectively. In this way, the temperature conversion circuit 23 and the thermistor may be arranged inside and outside the display panel 0, respectively, which is conducive to improving the transparency of the display panel 0 when the display panel 0 is a transparent display panel 0. In the embodiment of the present disclosure with continued reference to FIG. 17, the temperature conversion circuit 23 further includes a first operation sub-circuit 231 a second operation sub-circuit 232 and a plurality of resistors. A resistance of the thermistor varies with temperature, so that an electrical signal in the thermistor varies with the resistance. The first operation sub-circuit 231 and the second operation sub-circuit 232 calculate and amplify the electrical signal on the thermistor, and output the electrical signal to the first controller 18 through an output terminal of the temperature conversion circuit 23. It should be noted that the first operation sub-circuit and the second operation sub-circuit in the embodiment of the present disclosure may be operational amplifiers. Meanwhile, the temperature conversion circuit 23 shown in FIG. 23 is described as merely an example in the embodiment of the present disclosure, and other circuits for temperature/voltage conversion through the thermistor are within the protection scope of the present application.

In some embodiments, the display panel 0 further includes a plurality of second display signal lines. Orthographic projections of the first sensing signal line 10 and the second sensing signal line 22 on the base substrate 1 are overlapped with an orthographic projection of the second display signal lines on the base substrate 1 respectively, and the orthographic projections of the first sensing signal line 10 and the second sensing signal line 11 on the base substrate 1 are not overlapped with each other. In the embodiment of the present disclosure, when the display panel 0 is the transparent display panel 0, the first sensing signal line 21 and the second sensing signal line 22 connected to the thermistor may be designed to overlap with the orthographic projections of the second display signal lines on the display panel on the base substrate 1 respectively, so as to avoid the first sensing signal line 21 and the second sensing signal line 22 additionally provided from affecting the light transmittance and a pixel aperture ratio of the transparent display panel 0. Specifically, in the transparent display panel 0, the existing first control signal line 10 on the transparent display panel 0 may have an opaque structure, so that the first sensing signal line 21 and the second sensing signal line 11 are arranged between the opaque structure of the display panel 0 and the base substrate 1. In this manner, an area of a light-transmitting area in the transparent display panel 0 is not occupied greatly, the light transmittance of the transparent display panel 0 is not affected, and light emission of the sub-pixels d in the display region DR is not blocked. It should be noted that in some embodiments, the first display signal line and the second display signal line described above may be a same display signal line or a same type of display signal line, which is not limited in the embodiment of the present disclosure.

In some embodiments, the first controller 18 may be disposed outside the display panel 0. Particularly when the display panel 0 is applied to a glass window, the first controller 18 may be provided on a System on a Chip (SOC for short) board outside the display panel 0. In this way, the area of the transparent region TR of the transparent display panel 0 can be further increased. Meanwhile, when the display panel 0 is applied to the glass window, the first controller 18 can also control an external refrigeration system of the display panel 0 according to the temperature of the display panel 0 to cool the display panel 0. The external refrigeration system may be an air conditioning system or other cooling systems.

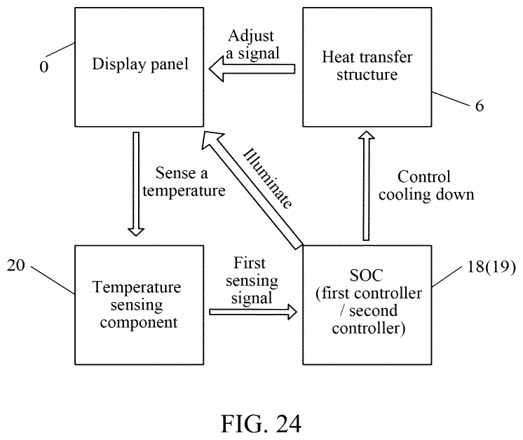

In some embodiments, the display panel 0 may further include a second controller 19. As shown in FIG. 24, the second controller 19 is configured to control the sub-pixels d in the display panel 0 to emit light according to the first sensing signal. In the embodiment of the present disclosure, the second controller 19 controls each pixel to emit light according to an image to be displayed. Since the first sensing signal generated by the temperature sensing component 20 according to the temperature of the display panel 0 can be converted into temperature information of the display panel 0, when the temperature of the display panel 0 is excessively high, the second controller 19 can reduce power of the sub-pixels d in the display panel 0 according to the first sensing signal to reduce the heat generated by the sub-pixels d. Or, the sub-pixel d can be controlled to display a prompt image to remind relevant personnel to cool down the display panel 0. It should be noted that, in some embodiments, the first controller 18 and the second controller 19 may be integrated on a same SOC.

A display device is further provided in an embodiment of the present disclosure. The display device includes the display panel as provided in any of the aforementioned embodiments.

The display device according to the exemplary embodiment of the present disclosure may be any product or component with a display function, such as a display panel 0, a flexible wearable device, a mobile phone, a tablet computer, a television, a display, a laptop computer, a digital photo frame, a navigator and the like. Other essential components of the display device should be understood as being included in the display device by those of ordinary skill in the art, which will not be described herein in detail, and should not be regarded as a limitation on the present disclosure.

It is to be understood that the above embodiments are only exemplary embodiments employed for the purpose of illustrating the principles of the present disclosure, however the present disclosure is not limited thereto. To those of ordinary skills in the art, various modifications and improvements may be made without departing from the essence and substance of the present disclosure, and these modifications and improvements are also considered to be within the scope of the present disclosure.

1. A display panel comprising, at least a display region that comprises a base substrate and a plurality of sub-pixels disposed on the base substrate, wherein each of the sub-pixels at least comprises a light emitting device that is located in the display region; the light emitting device comprises a first electrode, a light emitting layer and a second electrode disposed in sequence in a direction facing away from the base substrate; the display panel further comprises a heat conduction structure disposed on a side of each first electrode facing away from the light emitting layer, and an orthographic projection of the heat conduction structure on the base substrate at least partially overlaps with an orthographic projection of the first electrode on the base substrate.

2. The display panel of claim 1, wherein the heat conduction structures and the light emitting devices are disposed in one-to-one correspondence.

3. The display panel of claim 1, further comprising a heat dissipation structure disposed on a side of the heat conduction structure facing away from the first electrode.

4. The display panel of claim 3, wherein the heat conduction structure comprises a first heat conduction sheet, a semiconductor layer, and a second heat conduction sheet arranged in sequence in a direction facing away from the light emitting layer; wherein the first heat conduction sheet is connected to the first electrode of the light emitting device, and the second heat conduction sheet is connected to the heat dissipation structure.

5. The display panel of claim 3, wherein the heat conduction structure comprises a first heat conduction sheet, a semiconductor layer, and a second heat conduction sheet arranged in sequence in a direction facing away from the light emitting layer; wherein an insulating heat conduction layer is provided between the first heat conduction sheet and the first electrode of the light emitting device, and the second heat conduction sheet is connected to the heat dissipation structure.

6. The display panel of claim 5, wherein the display panel is divided into a plurality of pixel units, each of the pixel units comprises a plurality of sub-pixels, and at least part of heat conduction structures corresponding to each pixel unit is in an integral structure.

7. The display panel of claim 4, wherein the heat conduction structure and the heat dissipation structure are disposed on a side of the base substrate close to the first electrode.

8. The display panel of claim 4, wherein the heat conduction structure is disposed on a side of the base substrate close to the first electrode, and the heat dissipation structure is disposed on a side of the base substrate facing away from the first electrode.

9. The display panel of claim 3, wherein a material of the heat dissipation structure comprises a copper alloy.

10. The display panel of claim 1, wherein the heat conduction structure is disposed on a side of the base substrate facing away from the light emitting device.

11. The display panel of claim 1, further comprising a plurality of first control signal lines and a plurality of second control signal lines; wherein one of the heat conduction structures is electrically connected to one of the first control signal lines and one of the second control signal lines.

12. The display panel of claim 11, further comprising a plurality of first display signal lines, wherein orthographic projections of the first control signal lines and the second control signal lines on the base substrate overlap with an orthographic projections of the first display signal lines on the base substrate respectively, and the orthographic projections of the first control signal lines and the second control signal lines on the base substrate are not overlapped with each other; or
the heat conduction structure comprises a first heat conduction sheet, a semiconductor layer, and a second heat conduction sheet disposed in sequence in a direction facing away from the light emitting layer, and the first control signal lines and the second control signal lines are electrically connected with the semiconductor layer respectively and are disposed in a same layer as the semiconductor layer; or
the heat conduction structures are arranged in an array on a side of the base substrate close to the first electrode, and a first control signal line and a second control signal line connected to a same heat conduction structure are located on two opposite sides of the heat conduction structure; or
the display panel comprises a plurality of heat conduction structures arranged sequentially in a column direction; heat conduction structures located in a same column are connected with a same first control signal line and a same second control signal line; heat conduction structures in columns are divided into a plurality of heat conduction structure groups, and heat conduction structures in different groups are different; and
a first control signal line to which heat conduction structures in a heat conduction structure group are connected is shorted, and a second control signal line to which the heat conduction structures in the heat conduction structure group are connected is shorted.

13-15. (canceled)

16. The display panel of claim 12, wherein heat conduction structures in columns are divided into three heat conduction structure groups, and heat conduction structures in different groups are different; and
every three columns of the heat conduction structures are located in sequence in three different heat conduction structure groups.

17. The display panel of claim 11, wherein the heat conduction structures are divided into a plurality of heat conduction structure groups arranged in an array; and
a first control signal line to which heat conduction structures in a heat conduction structure group are connected is shorted, and a second control signal line to which the heat conduction structures in the heat conduction structure group are connected is shorted.

18. The display panel of claim 3, further comprising a first drive circuit that is electrically connected to the heat conduction structure;
the first drive circuit is configured to provide a first control signal to the heat conduction structure according to a temperature of the display panel; and
the heat conduction structure is configured to transfer heat emitted by the light emitting device under control of the first control signal.

19. The display panel of claim 1, further comprising a temperature sensing component and a first controller; wherein the temperature sensing component is disposed on a side of the first electrode facing away from the light emitting layer, and an orthographic projection of the temperature sensing component on the base substrate at least partially overlaps with the orthographic projection of the first electrode on the base substrate; the temperature sensing component is configured to generate a first sensing signal according to the temperature of the display panel, and the first controller is configured to control operation of the heat conduction structure according to the first sensing signal.

20. The display panel of claim 19, further comprising at least one first sensing signal line and at least one second sensing signal line; wherein the at least one first sensing signal line and the at least one second sensing signal line are connected to the temperature sensing component respectively; or
the display panel further comprises a plurality of second display signal lines; wherein orthographic projections of the first sensing signal lines and the second sensing signal lines on the base substrate are respectively overlapped with an orthographic projection of the second display signal lines on the base substrate, and the orthographic projections of the first sensing signal lines and the second sensing signal lines on the base substrate are not overlapped with each other; or
the display panel further comprises a temperature conversion circuit; wherein the temperature conversion circuit is configured to convert the first sensing signal into an electrical signal and transmit the electrical signal to the first controller.

21-22. (canceled)

23. The display panel of claim 19, wherein the temperature sensing component comprises at least one of a thermistor or a thermocouple.

24. The display panel of claim 1, wherein the display panel is a transparent display panel, the display panel further comprises a transparent region, and the orthographic projection of the heat conduction structure on the base substrate is not overlapped with the transparent region.

25. A display device, comprising the display panel of claim 1.
